(19) United States
(12) Patent Application Publication
(10) Pub. No.: US 2026/0319037 A1
(43) Pub. Date: Oct. 15, 2026

(54) TUNABLE SHEATH WAVE TRAP FOR MAGNETIC RESONANCE TOMOGRAPHY DEVICES

(71) Applicant: Siemens Healthineers AG, Forchheim (DE)

(72) Inventors: Matthias Malzacher, Nürnberg (DE); Vincent Kelber, Bamberg (DE)

(21) Appl. No.: 19/630,667

(22) Filed: Mar. 27, 2026

(30) Foreign Application Priority Data
Apr. 14, 2025 (DE) 10 2025 114 547.4

(51) Int. Cl. G01R 33/36

(52) U.S. Cl. CPC G01R 33/3685; G01R 33/3628

(57) ABSTRACT

A sheath wave trap for a magnetic resonance tomography device includes a dielectric body for arranging on an electrical cable in a patient tunnel of the magnetic resonance tomography device and a metallic tuning body on or in the dielectric body, which is configured to provide a variable capacitance with the electrical cable. The sheath wave trap further includes an adjusting element, which, in the position according to use of the sheath wave trap on the electrical cable, is configured to vary a relative position of the metallic tuning body in relation to the electrical cable.

The present patent document claims the benefit of German Patent Application

No. 10 2025 114 547.4, filed Apr. 14, 2025, which is hereby incorporated by reference in its entirety.

### TECHNICAL FIELD

The disclosure relates to a sheath wave trap for a magnetic resonance tomography device as well as to a local coil and to a magnetic resonance tomography device with the sheath wave trap.

### BACKGROUND

Magnetic resonance tomography devices are imaging apparatuses that, in order to map an examination object, align nuclear spins of the examination object with a strong external magnetic field and excite them into precession about this alignment by way of an alternating magnetic field. The precession and/or the return of the spin from this excited state into a state with lower energy in turn generates an alternating magnetic field as the response, which is received via antennas.

With the aid of magnetic gradient fields, a spatial encoding is impressed upon the signals, which subsequently makes it possible to assign the received signal to a volume element. The received signal is then evaluated and a three-dimensional imaging representation of the examination object is provided. For receiving the signal, local receiving antennas, (also referred to as local coils), may be used. The local coils, in order to achieve a better signal-to-noise ratio, may be arranged directly on the examination object.

In certain MR systems, the frequency of the alternating magnetic fields lies in the range of 20 MHz (for basic field strengths of 0.5 T) to 300 MHz (7 T).

Electrical cables exposed to these radiofrequency alternating fields act as antennas and may build up hazardous voltages on the surface. These are therefore segmented by what are known as sheath wave traps, which are used in particular for the supply cable of the RF body coils, which are exposed to these fields in a patient tunnel. The sheath wave traps used to date may be resonantly tuned to the frequency of the excitation fields and block a propagation of alternating currents with the frequency along the supply cable. The supply cable is thus divided into small pieces smaller than the wavelength on the supply cable, meaning that high voltages are unable to build up.

Due to component tolerances, the resonance of the sheath wave trap may have to be tuned to the frequency of the excitation fields, for example, by soldering additional tuning elements or bending coil windings.

### SUMMARY

The object of the present disclosure is therefore to provide a sheath wave trap that is easier to tune.

This object is achieved by a sheath wave trap as well as by a local coil and a magnetic resonance tomography device as described herein. The scope of the present disclosure is defined solely by the appended claims and is not affected to any degree by the statements within this summary. The present embodiments may obviate one or more of the drawbacks or limitations in the related art.

The sheath wave trap is provided for a magnetic resonance tomography device, in particular for use in a patient tunnel of the magnetic resonance tomography device. The sheath wave trap has a dielectric body for arranging on an electrical cable in the patient tunnel of the magnetic resonance tomography device. In this context, dielectric is understood to mean that the body itself is non-conductive or high-resistance, meaning that an ohmic resistance of the body is negligible compared to a radiofrequency resistor due to capacitive and/or inductive interaction between the cable and the tuning body that is explained in the following. The dielectric body may be shaped on the cable, for example, so that it is applied from one side.

In certain examples, the design of the dielectric body may include two or more parts, which may be applied to the cable as half shells from both or multiple sides and surround the cable. In an alternative example, a one-piece embodiment with a hole or feedthrough, through which the electrical cable is guided, may also be possible. The dielectric body may be shaped such that, in the proper arrangement on the cable, a relative position of the dielectric body and/or a tuning body arranged thereon or therein in relation to the cable does not vary without a tuning procedure during operation.

In this context, cable is understood to mean both a single-core cable as well as a multi-core cable with multiple conductors or conductor pairs that are insulated from one another. The cable may also have coaxial conductors.

The sheath wave trap further includes a metallic tuning body positioned on a surface of the dielectric body or within the dielectric body. In this context, metallic is understood to mean that the tuning body has an electrical resistance for radiofrequency current, in particular at the frequency of the excitation signal, which is comparable to a body made from metal. The metallic tuning body may also be formed from a non-conductive dielectric body with at least one inner or outer layer of metal. The metal may feature gold, silver, copper, or aluminum, for example. In certain examples, the metal is not ferromagnetic.

The metal body is configured to provide a variable capacitance with the cable.

To this end, the sheath wave trap has an adjusting element, which, in the position according to use of the sheath wave trap on the cable, is configured to vary a relative position of the metallic tuning body in relation to the cable. In this context, a relative position is also understood to mean a change in shape of the tuning body, (e.g., of the curvature), in which distances at least of parts of the tuning body in relation to the cable and therefore the capacitance between the tuning body and the cable change. The change may be reproducible here. For example, with a predetermined position of the adjusting element, it may be possible to recreate an associated predetermined relative position. Different embodiments of the adjusting element are disclosed in the following.

Advantageously, the tuning body, in connection with the adjusting element, enables a simple tuning of the sheath wave trap and a simple attachment without ohmic electrical connection to the electrical cable.

The local coil and the magnetic resonance tomography device share the advantages of the sheath wave trap as described herein.

In one embodiment of the sheath wave trap, the adjusting element is embodied to vary a distance of the metallic tuning body from the cable. In this context, this may involve a linear displacement of at least a part of the tuning body in the direction toward the electrical cable, (e.g., by a thread). A lateral displacement is also conceivable, in which a distance, averaged over an area, of the tuning body from the cable changes, meaning that the capacitance of the tuning body varies compared to the cable.

Advantageously, a displacement for varying the distance may be implemented in a simple manner and enables a precise tuning.

In one conceivable embodiment of the sheath wave trap, the adjusting element is embodied to vary a shape of the metallic tuning body. In particular, it is conceivable that the metallic tuning body is elastic, wherein the adjusting element is embodied to exert a variable pressure on the metallic tuning body, meaning that its shape, the distance, averaged over the area, of the tuning body from cable, and thus the capacitance of the metallic tuning body compared to the cable vary.

Advantageously, a change in shape of an elastic tuning body may be implemented in a particularly simple and precise manner.

In one embodiment of the sheath wave trap, the dielectric body has a cavity, in which the metallic tuning body is arranged. In certain examples, in the position according to use of the sheath wave trap, the cavity may extend along the electrical cable and/or tangentially around the cable.

The arrangement in a cavity provides a compact and electrically safe construction of the sheath wave trap and simplifies cleaning to provide hygiene.

In one conceivable embodiment of the sheath wave trap, in the position according to use of the sheath wave trap on the cable, the metallic tuning body has a concave contour in relation to the cable. By exerting pressure and/or tension on the tuning body, the adjusting element may vary its shape and thus the capacitance in relation to the electrical cable.

Advantageously, a concave shape, in particular with an elastic tuning body, enables a simple construction for varying capacitance by pressure and in doing so at the same time enables the tuning body to be laid in the sheath wave trap.

The above-described properties, features, and advantages of the disclosure and the manner in which they are achieved are made more clearly and distinctly intelligible in conjunction with the following description of the embodiments, which are explained in greater detail making reference to the drawings.

### BRIEF DESCRIPTION OF THE DRAWINGS

FIG. 1 depicts a schematic representation of an embodiment of a magnetic resonance tomography device with a local coil.

FIG. 2 depicts a cross-section through an embodiment of a sheath wave trap in the vertical cross-section.

FIG. 3 depicts a perspective view of an embodiment of a sheath wave trap.

FIG. 4 depicts a cross-section through an embodiment of a sheath wave trap in the vertical cross-section.

### DETAILED DESCRIPTION

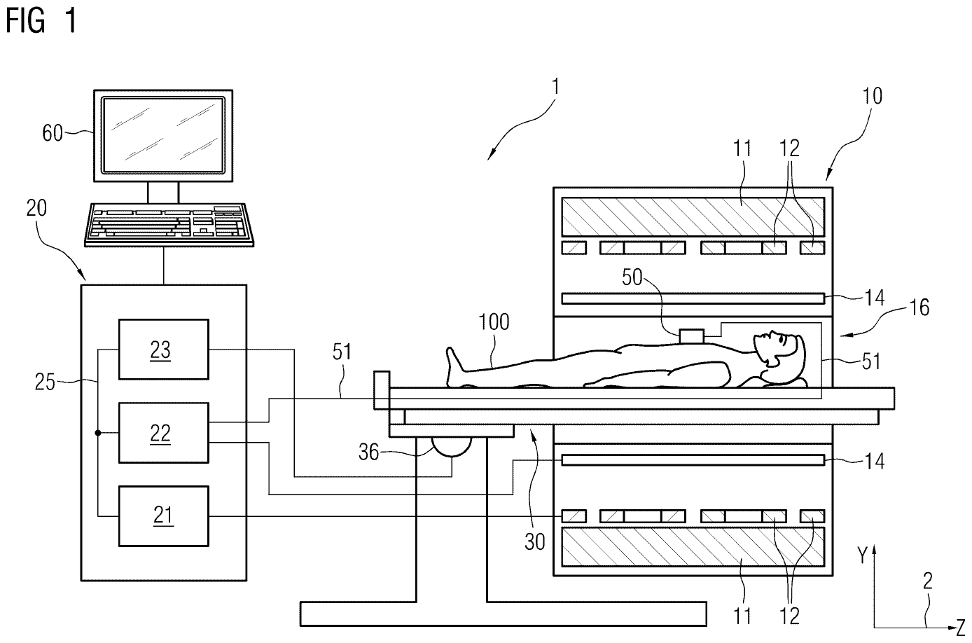

FIG. 1 shows a schematic representation of an embodiment of a magnetic resonance tomography device 1 for image capture with the local coil 50.

The magnet unit 10 has a field magnet 11 that generates a static magnetic field B0 for aligning the nuclear spins of samples or of the patient 100 in a recording region. The recording region is characterized by a homogenous static magnetic field B0, wherein the homogeneity relates, in particular, to the magnetic field strength and/or the magnitude. The recording region may be spherical and may be arranged in a patient tunnel 16 that extends in a longitudinal direction 2 through the magnet unit 10.

A patient couch 30 may be moved in the patient tunnel 16 by the displacement unit 36.

The field magnet 11 may be a superconductive magnet, which may provide magnetic fields with a magnetic flux density of up to 3T or higher. For lower field strengths, it is also possible to use permanent magnets or electromagnets with normally conductive coils.

The magnet unit 10 further includes gradient coils 12, which are configured to superimpose variable magnetic fields in three spatial directions on the magnetic field B0 for the purpose of spatial discrimination of the acquired mapping regions in the examination volume. The gradient coils 12 may be coils made of normally conductive wires that may generate mutually orthogonal fields of the static magnetic field B0 in the examination volume.

The magnet unit 10 has a body coil 14 configured to radiate a radiofrequency signal supplied via a signal cable into the examination volume. For some image captures, a local coil 50 may also be provided as transceiver antenna.

A control unit 20 supplies the magnet unit 10 with the different signals for the gradient coils 12 and the body coil 14 and evaluates the received signals.

Thus, the control unit 20 has a gradient controller 21 configured to supply the gradient coils 12 via supply cables with variable currents which provide the desired gradient fields in the examination volume in a temporally coordinated manner.

Furthermore, the control unit 20 has a radiofrequency unit 22 configured to generate a radiofrequency pulse with a predetermined temporal sequence, amplitude, and spectral power distribution to excite a magnetic resonance of the nuclear spins in the patient 100. In this context, it is possible to reach pulse powers in the kilowatt range. The excitation signals are radiated into the patient 100 via the body coil 14.

The local coil 50 captures the magnetic resonance signals emitted from the patient 100 and forwards the signals to the magnetic resonance tomography device 1.

The local coil 50 is arranged as close as possible to the patient 100 and is connected to the magnetic resonance tomography device 1 by an electrical cable 51, in order, for example, to forward the received magnetic resonance signals, to be supplied with energy for circuits of the local coil 50 as well as to obtain control commands, in order to bring the local coil 50 into a protected state during the excitation pulses.

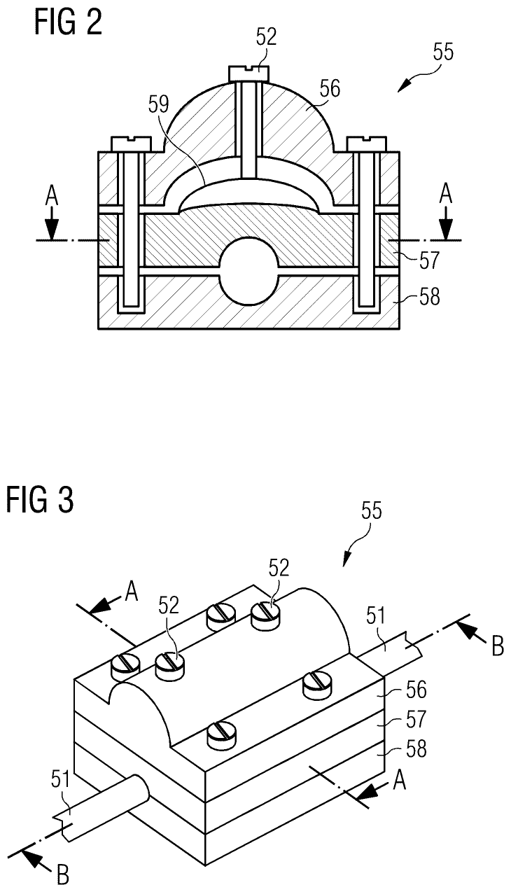

In this context, the electrical cable 51 acts as a receiving antenna for the excitation pulses. If a length of the electrical cable 51 comes into a region that corresponds to greater than one tenth or one fifth of the wavelength of the excitation pulse in the patient tunnel, then considerable voltage may build up along the electrical cable 51 due to what are known as sheath waves. In order to prevent or to reduce this, the electrical cable 51 is divided by what are known as sheath wave traps 55 into smaller segments from an electrical perspective, at least for signals of the frequency of the excitation pulses. In this context, the sheath wave trap 51 may be resonantly tuned to the frequency of the excitation pulses. The precise tuning is critical and is made difficult by component tolerances of electrical components that are used. One advantageous embodiment of a sheath wave trap with simplified tuning is shown in the following in relation to FIG. 2.

A controller 23 communicates with the gradient controller 21 and the radiofrequency unit 22 via a signal bus 25. A user may make inputs to the control unit 20 via an operator control terminal 60.

FIG. 2 shows a cross-section through an embodiment of a sheath wave trap in the vertical cross-section along line A-A.

The shown embodiment of the sheath wave trap 55 has a dielectric body, which includes at least three parts: a cover 56, a shaped body 57, and a bottom 58. The bottom 58 and the shaped body 57 each have a groove, in which the electrical cable 51 is fixed, (e.g., by clamping), in the position according to use of the sheath wave trap 55 on the electrical cable 51.

The shaped body 57 is arranged between the bottom 58 and the cover 56. The side of the shaped body 57 facing toward the cover 56 may have a flat surface or a convex surface that curves around the cable 51 in use. The cover 56 has a corresponding concave recess. In the arrangement according to use of cover 56 on the shaped body, this forms a cavity that extends in parallel with the cable and is arranged in the metallic tuning body 59.

In FIG. 2, the metallic tuning body 59 is implemented by a curved, flexible metal sheet. The metal sheet is arranged in the cavity formed by the cover 56 and the shaped body 57. In this context, the shaped body 56 has a locating area for edges of the metal sheet. The locating area in this case is embodied at least on one side, such that the edge of the metal sheet may vary a position of locating points or a locating line on the shaped body 57 in the event of a change in shape of the metal sheet due to the adjusting element 52.

In FIG. 2, the adjusting element 52 is implemented by a movable element which, starting from the cover, is able to exert an adjustable force onto the metal sheet or the metallic tuning body 59 in the direction toward the shaped body 57. For example, the adjusting element 52 may be implemented by a screw that, by a thread in the cover 56, exerts the force on the metallic tuning body 59 toward the shaped body 57 and brings this into a flatter shape, which in use is closer to an electrical cable 51 in the groove and thus forms a greater capacitance with the electrical cable 51. In order to enable the change in shape, at least one edge of the metal sheet slides on the locating area laterally away from the groove for the electrical cable 51. This embodiment allows a particularly simple assembly of the sheath wave trap 55.

The adjusting element 52 remains in the sheath wave trap 55, even once the tuning procedure has been completed. In certain examples, the adjusting element 52 may secure the relative position of the tuning body 59, even during operation among the acting vibrations, accelerations, and electromagnetic forces. For this purpose, the adjusting element 52 may be secured against shifting in a thread in the cover 56 by a self-securing thread. Other fixings for the adjusting element 52 are also possible, such as a sealing lacquer, locknut, splint, or other device. The adjusting element 52 may be arranged as a headless screw countersunk in the cover, so that the sheath wave trap 55 does not have any protruding parts.

In certain examples, the metallic tuning body 59 may not vary its shape, but rather only varies its relative position in relation to the shaped body 57. This may be achieved by the cavity embodied between cover 56 and the shaped body 57 being larger than the metallic tuning body 59, meaning that the metallic tuning body 59 may be moved toward or away from the shaped body 57 with the electrical cable 51 by the adjusting element 52. To this end, instead of the locating area, the cavity is continued in the form of a groove in the shaped body 57, for example. In this context, the adjustable position of the metallic tuning body 57 may be determined by the adjusting element 92 to which the metallic tuning body is fastened. In such an example, at least in the direction of movement of the tuning element, the distance between the metallic tuning body 59 and adjusting element 52 may be specified, and not only a force toward the electrical cable 51 but also away from the electrical cable 51 may be exerted on the metallic tuning body 59 by the adjusting element 52. In this context, it is conceivable that the metallic tuning body 59 is not flexible but rather is rigid.

FIG. 3 shows a perspective view of an embodiment of a sheath wave trap, as shown in FIG. 2, for example.

In FIG. 3, the electrical cable 51 may be seen, which is clamped in a groove between the bottom 58 and the shaped body 57. The cavity between shaped body and cover may be closed, as depicted here, in order on the one hand to prevent contamination for hygiene reasons and on the other hand to prevent touching of the metallic tuning body 59 for safety reasons. For the same reason, the adjusting elements 52 may be manufactured from a non-conductive material, for example, screws made of a plastic such as nylon or Teflon.

The bottom 58, shaped body 57, and cover 56 are connected to one another by a retaining device, e.g., screws in the corners. The bottom 58, shaped body 57, and/or cover 56 may individually be made of non-conductive material. Other fastening devices are also conceivable, e.g., tongues and grooves that interlock when put together. In certain examples, the bottom 58, shaped body 57, and cover 56 may be adhesively bonded.

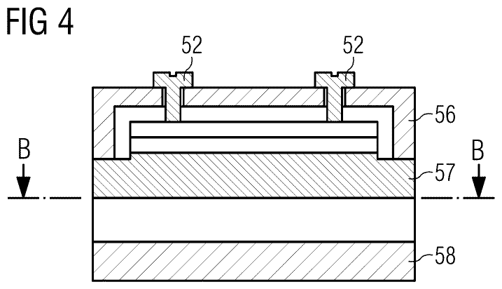

FIG. 4 shows a vertical cross-section through the sheath wave trap from FIG. 3 along the line B-B. In this cross-section, in particular it is possible to see the cavity for the electrical cable 51, which extends between the bottom 58 and shaped body 57 through the sheath wave trap 55. The cavity formed by the cover 56 and shaped body 57 extends in parallel with this, with the metallic tuning body 59 therein.

It is to be understood that the elements and features recited in the appended claims may be combined in different ways to produce new claims that likewise fall within the scope of the present disclosure. Thus, whereas the dependent claims appended below depend on only a single independent or dependent claim, it is to be understood that these dependent claims may, alternatively, be made to depend in the alternative from any preceding or following claim, whether independent or dependent, and that such new combinations are to be understood as forming a part of the present specification.

While the present disclosure has been described above by reference to various embodiments, it may be understood that many changes and modifications may be made to the described embodiments. It is therefore intended that the foregoing description be regarded as illustrative rather than limiting, and that it be understood that all equivalents and/or combinations of embodiments are intended to be included in this description.

1. A sheath wave trap for a magnetic resonance tomography device, the sheath wave trap comprising:
a dielectric body for arranging on an electrical cable in a patient tunnel of the magnetic resonance tomography device;
a metallic tuning body arranged on the dielectric body or in the dielectric body, wherein the metallic tuning body is configured to provide a variable capacitance with the electrical cable; and
an adjusting element, which, in a position according to use of the sheath wave trap on the electrical cable, is configured to vary a relative position of the metallic tuning body in relation to the electrical cable and/or a shape of the metallic tuning body.

2. The sheath wave trap of claim 1, wherein the adjusting element is configured to vary a distance of the metallic tuning body from the electrical cable.

3. The sheath wave trap of claim 2, wherein the adjusting element is configured to vary the shape of the metallic tuning body.

4. The sheath wave trap of claim 3, wherein the dielectric body comprises a cavity and
wherein the metallic tuning body is arranged in the cavity of the dielectric body.

5. The sheath wave trap of claim 4, wherein, in the position according to use of the sheath wave trap on the electrical cable, the metallic tuning body has a concave contour in relation to the electrical cable.

6. The sheath wave trap of claim 1, wherein the adjusting element is configured to vary the shape of the metallic tuning body.

7. The sheath wave trap of claim 1, wherein the dielectric body comprises a cavity and
wherein the metallic tuning body is arranged in the cavity of the dielectric body.

8. The sheath wave trap of claim 7, wherein, in the position according to use of the sheath wave trap on the electrical cable, the metallic tuning body has a concave contour in relation to the electrical cable.

9. A local coil for a magnetic resonance tomography device, the local coil comprising:
a sheath wave trap having:
a dielectric body for arranging on an electrical cable in a patient tunnel of the magnetic resonance tomography device;
a metallic tuning body arranged on the dielectric body or in the dielectric body, wherein the metallic tuning body is configured to provide a variable capacitance with the electrical cable; and
an adjusting element, which, in a position according to use of the sheath wave trap on the electrical cable, is configured to vary a relative position of the metallic tuning body in relation to the electrical cable and/or a shape of the metallic tuning body.

10. The local coil of claim 9, wherein the adjusting element is configured to vary a distance of the metallic tuning body from the electrical cable.

11. The local coil of claim 9, wherein the adjusting element is configured to vary the shape of the metallic tuning body.

12. The local coil of claim 9, wherein the dielectric body comprises a cavity and
wherein the metallic tuning body is arranged in the cavity of the dielectric body.

13. The local coil of claim 12, wherein, in the position according to use of the sheath wave trap on the electrical cable, the metallic tuning body has a concave contour in relation to the electrical cable.

14. A magnetic resonance tomography device comprising:
a sheath wave trap having:
a dielectric body for arranging on an electrical cable in a patient tunnel of the magnetic resonance tomography device;
a metallic tuning body arranged on the dielectric body or in the dielectric body, wherein the metallic tuning body is configured to provide a variable capacitance with the electrical cable; and
an adjusting element, which, in a position according to use of the sheath wave trap on the electrical cable, is configured to vary a relative position of the metallic tuning body in relation to the electrical cable and/or a shape of the metallic tuning body.

15. The magnetic resonance tomography device of claim 14, wherein the adjusting element is configured to vary a distance of the metallic tuning body from the electrical cable.

16. The magnetic resonance tomography device of claim 14, wherein the adjusting element is configured to vary the shape of the metallic tuning body.

17. The magnetic resonance tomography device of claim 14, wherein the dielectric body comprises a cavity and
wherein the metallic tuning body is arranged in the cavity of the dielectric body.

18. The magnetic resonance tomography device of claim 17, wherein, in the position according to use of the sheath wave trap on the electrical cable, the metallic tuning body has a concave contour in relation to the electrical cable.
